(19) United States
(12) Patent Application Publication
(10) Pub. No.: US 2024/0347369 A1
(43) Pub. Date: Oct. 17, 2024

(54) DISSOLVING ADHESIVE BASE STRUCTURE TO RELEASE ELECTRONIC COMPONENT

(71) Applicant: Infineon Technologies AG, Neubiberg (DE)

(72) Inventors: Frank SINGER, Regenstauf (DE); Thorsten SCHARF, Lappersdorf (DE); Evelyn NAPETSCHNIG, Villach (AT)

(73) Assignee: Infineon Technologies AG, Neubiberg (DE)

(21) Appl. No.: 18/605,019

(22) Filed: Mar. 14, 2024

(30) Foreign Application Priority Data
Apr. 12, 2023 (DE) 10 2023 109 165.4

(51) Int. Cl. H01L 21/683; H01L 21/56; H01L 21/60

(52) U.S. Cl. CPC H01L 21/6836; H01L 21/568; H01L 21/60; H01L 2021/6006; H01L 2221/68318; H01L 2221/68354

(57) ABSTRACT

A method is disclosed. In one example, the method comprises mounting an electronic component on an adhesive base structure on a temporary carrier, and dissolving at least part of the base structure by irradiating the base structure with electromagnetic radiation to thereby release the electronic component.

### CROSS-REFERENCE TO RELATED APPLICATION

This Utility patent application claims priority to German Patent Application No. 10 2023 109 165.4 filed Apr. 12, 2023, which is incorporated herein by reference.

### BACKGROUND OF THE INVENTION

### Field of the Invention

The present invention relates to a method and to an equipment.

### Description of the Related Art

Packages may be encapsulated electronic chips with electrical connects extending out of the encapsulant and being connectable to an electronic periphery. Before packaging, a semiconductor wafer is separated into a plurality of electronic chips. After separating the wafer into the separated electronic chips, the electronic chips of the wafer may be picked and placed to a destination.

### SUMMARY OF THE INVENTION

There may be a need to handle electronic components efficiently.

According to an exemplary embodiment of a first aspect, a method is provided, wherein the method comprises mounting an electronic component on an adhesive base structure on a temporary carrier, and dissolving at least part of the base structure by irradiating the base structure with electromagnetic radiation to thereby release the electronic component.

According to another exemplary embodiment of the first aspect, an equipment is provided which comprises an electromagnetic radiation source configured for irradiating at least a mounting portion of an adhesive base structure on a temporary carrier on which mounting portion an electronic component is mounted to thereby release the electronic component from the mounting portion, and an alignment unit for aligning a mutual position between, on the one hand, a carrier for carrying the electronic component and, on the other hand, the released electronic component (for instance falling downwardly by gravity) so that the (for instance downwardly falling) electronic component is transferred and lands on the carrier.

### BRIEF DESCRIPTION OF THE DRAWINGS

The accompanying drawings, which are included to provide a further understanding of exemplary embodiments of the invention and constitute a part of the specification, illustrate exemplary embodiments of the invention.

In the drawings:

FIG. 1 illustrates an equipment according to an exemplary embodiment.

FIG. 2 illustrates an equipment according to an exemplary embodiment.

FIG. 3 illustrates an equipment according to an exemplary embodiment.

FIG. 4 to FIG. 6 show different views of structures obtained during carrying out a method according to an exemplary embodiment.

FIG. 7 to FIG. 9 show different views of structures obtained during carrying out a method according to an exemplary embodiment.

FIG. 10 illustrates an equipment according to an exemplary embodiment.

FIG. 11 illustrates an equipment according to an exemplary embodiment.

FIG. 12 and FIG. 13 show different views of structures obtained during carrying out a method according to an exemplary embodiment.

FIG. 14 and FIG. 15 show different views of structures obtained during carrying out a method according to an exemplary embodiment.

FIG. 16 to FIG. 21 show different views of structures obtained during carrying out a method according to an exemplary embodiment.

### DETAILED DESCRIPTION OF EXEMPLARY EMBODIMENTS

According to an exemplary embodiment of a first aspect, a method is provided, wherein the method comprises mounting an electronic component on an adhesive base structure on a temporary carrier, and dissolving at least part of the base structure by irradiating the base structure with electromagnetic radiation to thereby release the electronic component.

According to another exemplary embodiment of the first aspect, an equipment is provided which comprises an electromagnetic radiation source configured for irradiating at least a mounting portion of an adhesive base structure on a temporary carrier on which mounting portion an electronic component is mounted to thereby release the electronic component from the mounting portion, and an alignment unit for aligning a mutual position between, on the one hand, a carrier for carrying the electronic component and, on the other hand, the released electronic component (for instance falling downwardly by gravity) so that the (for instance downwardly falling) electronic component is transferred and lands on the carrier.

According to an exemplary embodiment of a second aspect, an equipment is provided which comprises an electromagnetic radiation source configured for irradiating at least a mounting portion of an adhesive base structure on which mounting portion an electronic component is mounted to thereby release the electronic component from the mounting portion, and a pick and place unit configured for, after the releasing, picking the electronic component at one side by a picking tool, thereafter further picking the electronic component at an opposing other side by another picking tool, and subsequently placing the electronic component with said one side on a carrier.

According to an exemplary embodiment of a third aspect, an equipment is provided which comprises an attaching unit configured for attaching a preform of the electronic component at one side to a temporary carrier during manufacture of the electronic component, a further attaching unit configured for attaching the electronic component at an opposing other side to a further temporary carrier, an electromagnetic radiation source configured for irradiating at least a mounting portion, on which mounting portion the electronic component is mounted, of an adhesive base structure, arranged between the further temporary carrier and the electronic component, to thereby release the electronic component from the mounting portion, and a pick and place unit configured for, after the releasing, picking the electronic component at said one side by a picking tool, and for subsequently placing the electronic component on a carrier.

According to an exemplary embodiment of a fourth aspect, a method is provided which comprises irradiating at least part of an adhesive base structure on a temporary carrier with electromagnetic radiation to thereby release a plurality of electronic components from the base structure to transfer the electronic components to a further carrier with changed pitch, and subsequently transferring the electronic components to and batch connecting (preferably batch soldering) the electronic components on one or more permanent carriers in accordance with the changed pitch.

According to an exemplary embodiment of the fourth aspect, an equipment is provided which comprises an electromagnetic radiation source configured for irradiating an adhesive base structure on a temporary carrier on which a plurality of electronic components is mounted to thereby release the electronic components from the base structure, and an alignment unit configured for aligning a mutual position between, on the one hand, a further carrier for carrying the electronic components and, on the other hand, the released electronic components to transfer the electronic components to the further carrier with changed (for example increased) pitch, wherein the alignment unit may be optionally further configured for aligning the further carrier with one or more permanent carriers for subsequently transferring the electronic components to and connecting (in particular by soldering, preferably by diffusion soldering) the electronic components with the one or more permanent carriers in accordance with the changed pitch.

According to an exemplary embodiment of the first aspect, an electronic component mounted on an adhesive base structure may be released therefrom by dissolving material of the base structure by electromagnetic radiation. Releasing the electronic component from the former adhesive base structure may be executed in an aligned way between electronic component and carrier so that the released electronic component is transferred (for example falls downwardly under gravity or is transferred in another way such as by gas pressure) and lands on the carrier, where it may rest or may be permanently connected. Advantageously, release of an electronic component from a previously adhesive base structure may be triggered by dissolving the adhesive material at least partially, so that the adhesive force is weakened or eliminated, causing the electronic component to be transferred (for instance to fall downwardly or to be transferred by gas pressure). Locating a carrier at a predicted landing position of the for example downwardly falling or otherwise transferred electronic component may allow to assemble the electronic component on the carrier in a very simple and reliable way. Hence, it may be made possible to handle electronic components efficiently. In particular, releasing a chip from a dicing tape may be accomplished without needle treatment from the back side, which may avoid conventional shortcomings related to die knocking, i.e. lateral abutment of adjacent electronic components being already separated from a wafer compound and being individually released by a needle lifting a respective electronic component from the back side. By substituting such a conventional approach by a laser-assisted process of dissipating an adhesive base structure, the risk of damage of the electronic component as well as the release effort may be significantly reduced.

According to an exemplary embodiment of the second aspect, an adhesive base structure with attached electronic component is selectively irradiated with electromagnetic radiation for triggering release of the electronic component from the adhesive base structure. This may allow a pick and place unit to pick the released electronic component at one side and further picking the picked electronic component at an opposing other side for placing the electronic component on a carrier. Selective irradiation of an adhesive base structure with electromagnetic radiation may cause a loss of an adhesive holding force which may enable a pick and place unit having at least two picking tools for handling the electronic component at both sides for putting it with a desired main surface towards a destination carrier or other surface. This architecture may allow to assemble the electronic component on a carrier or the like in a very simple and reliable way and to handle electronic components efficiently.

According to an exemplary embodiment of the third aspect, a preform of an electronic component is attached on one side to a temporary carrier. Furthermore, the electronic component may be attached at an opposing other side to a further temporary carrier, and the first temporary carrier may be removed. By irradiating an adhesive base structure between the further temporary carrier and the electronic component with electromagnetic radiation, the electronic component can be released from said adhesive base structure. This may make it possible to then pick the electronic component and place it on a destination carrier. Such an approach may make it possible to assemble the electronic component on the carrier in a very simple and reliable way and to handle electronic components efficiently.

According to an exemplary embodiment of the fourth aspect, an adhesive base structure on a temporary carrier and carrying multiple electronic components can be exerted to electromagnetic radiation for releasing the electronic components from the base structure. Thereby, they may be transferred from the temporary carrier to a further carrier (for instance a heat resistant carrier, such as a metal plate, with sticky surface) with changed (preferably increased) pitch compared with a pitch of the electronic components on the temporary carrier. After that, the electronic components may be transferred from the further carrier (from which they may be released) to one or more permanent carriers (such as a leadframe with leadframe structures) in accordance with the changed pitch. By simultaneously connecting (for example by batch soldering, i.e. a common solder process) of the electronic components, they may be fixedly connected to the permanent carrier or carriers. The further carrier may be removed from the obtained packages. Such a process may be highly efficient and may also include a transfer of pitch corresponding to wafer level to another pitch corresponding to leadframe level, or the like, and may be fully compatible with batch diffusion soldering.

The first, second, third and/or fourth aspect may be realized in isolation or in any combination.

### DESCRIPTION OF FURTHER EXEMPLARY EMBODIMENTS

In the following, further exemplary embodiments of the methods and the equipments will be explained.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). However, in other embodiments, the electronic component may also be of different type, such as a mechatronic member, in particular a mechanical switch, etc. In particular, the electronic component may be a semiconductor chip having at least one integrated circuit element (such as a diode or a transistor in a surface portion thereof. The electronic component may be a bare die or may be already packaged or encapsulated. Semiconductor chips implemented according to exemplary embodiments may be formed in silicon technology, gallium nitride technology, silicon carbide technology, etc.

In the context of the present application, the term “preform of electronic component” may particularly denote a semifinished product which already has part of a functionality but not yet the entire functionality of a readily manufactured electronic component. For example, a preform of an electronic component may still form part of a wafer compound before being separated therefrom. It is also possible that a preform of an electronic component still lacks a structural feature of a readily manufactured electronic component, such as all or part of pads necessary for being operative.

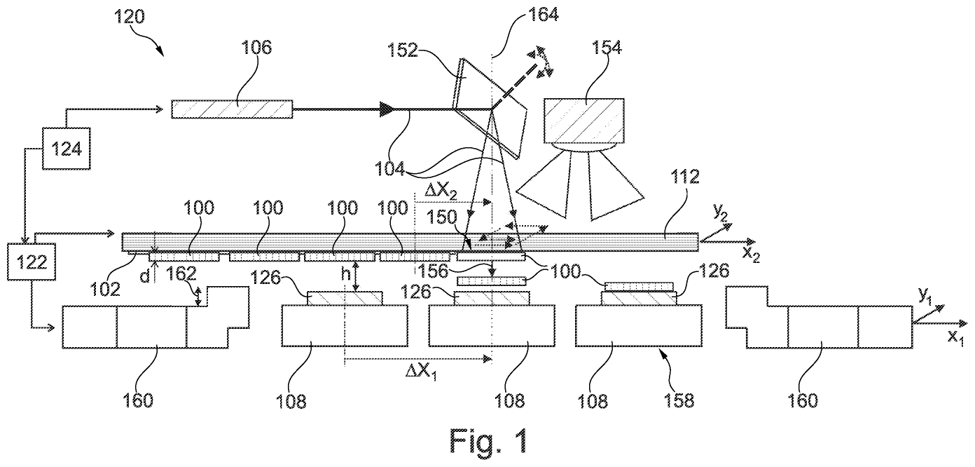

In the context of the present application, the term “carrier” (which may also be denoted as “electronic component carrier”) may particularly denote a support structure (which may be at least partially electrically conductive) which serves as a mechanical support for the electronic component(s) to be mounted thereon, and which may also contribute to the electric interconnection between the electronic component(s) and the periphery of the package. In other words, the carrier may fulfil a mechanical support function and an electric connection function. Such a carrier may be a permanent carrier, i.e. may form part of a readily manufactured package (see for example FIG. 1). A carrier may comprise or consist of a single part, multiple parts joined via encapsulation or other package components, or a subassembly of carriers. When the carrier forms part of a leadframe, it may be or may comprise a die pad. However, such a carrier may also be a temporary carrier, i.e. may be removed before completing manufacture of a package (see for example FIG. 18).

In the context of the present application, the term “temporary carrier” may particularly denote a support structure, for example shaped as a plate or a tape, which is to be attached only during part of a manufacturing process to an electronic component or a preform thereof, and which is to be removed from the electronic component of its preform before completing manufacture.

In the context of the present application, the term “adhesive base structure” may particularly denote a sticky physical structure which is configured for temporarily adhering to an electronic component for holding the electronic component, for example on a temporary carrier, by an adhesive force. For instance, the adhesive base structure may be an adhesive base layer, which may be for example continuous or patterned.

In the context of the present application, the term “mounting portion of the adhesive base structure” may particularly denote a subsection of an adhesive base structure on which subsection an electronic component is mounted with direct physical contact.

In the context of the present application, the term “dissolving at least part of the base structure” may particularly denote to dissipate or remove material of the base structure. For instance, dissolving the base structure may be embodied as converting material of the base structure from a solid phase into a gaseous phase. It is also possible that a base structure is dissolved by being evaporated or burnt off. For example, an adhesive base structure which can be dissolved may be embodied as a UV sensitive adhesive comprising triazene. Such an adhesive may be converted into gaseous constituents only (in particular carbon dioxide, aqueous vapor and/or nitrogen gases) by UV radiation.

In the context of the present application, the term “releasing the electronic component” may particularly denote triggering a detachment of the electronic component, for instance from a temporary carrier. Such a release of an electronic component may be triggered by deactivating an adhesive force of a previous adhesive base structure which held the electronic component at a temporary carrier or another structure. More generally, releasing an electronic component from a structure may be accomplished by reducing or eliminating a holding force.

In the context of the present application, the term “electromagnetic radiation source” may particularly denote an emitter of electromagnetic radiation. An electromagnetic radiation source may be configured for emitting electromagnetic radiation of a certain wavelength or range of wavelengths. For instance, an electromagnetic radiation source may be configured for emitting monochromatic or polychromatic light, for instance in an ultraviolet range, a visible range and/or an infrared range. For example, a laser may be implemented as electromagnetic radiation source.

In the context of the present application, the term “aligning a mutual position between a carrier and an electronic component being released and falling downwardly by gravity, so that the electronic component lands on the carrier” may particularly denote that a matching spatial relationship between the carrier and the electronic component may be specifically selected or adjusted so that when the previously attached electronic component loses its holding force, the electronic component falls downwardly under the force of gravity and will automatically reach the position of the carrier. In one embodiment, this may be achieved by a static arrangement between a previously attached electronic component and a carrier so that release of an attachment force of the electronic component will force the electronic component to fall vertically downwardly onto the carrier located vertically below. In another embodiment, this may be achieved by a relative motion between carrier and previously attached electronic component, wherein the relative motion and the falling trajectory will be coordinated with the positions between electronic component and carrier to ensure that the falling electronic component reaches the carrier.

In the context of the present application, the term “pick and place unit” may particularly denote an arrangement being configured for picking an electronic component or a preform thereof from an initial position and/or an initial orientation and placing it to a different final position and/or a different final orientation. For instance, this may be accomplished by a vacuum suction force or by gripping.

In the context of the present application, the term “pick and place unit comprising a picking tool and another picking tool” may particularly denote a pick and place unit having two different picking tools, such as two different vacuum suction elements or two different grippers. For instance, one picking tool may pick the electronic component at one main surface, and the other picking tool may pick the electronic component at the opposing other main surface.

In the context of the present application, the term “pitch” may particularly denote a center-to-center distance between adjacent electronic components and/or between adjacent functional electronic component portions.

In embodiments, different release strategies for releasing an electronic component from an adhesive base structure using electromagnetic radiation may be executed. Firstly, a desired exposure strategy can be selected, for example a homogenous exposure, a spiral scan, a greyscale lithography, etc. This selection may be made for example to achieve a lowest impact and a sufficient placement accuracy. For example, such a strategy may also be made in accordance with substrate exchange times which may be a relevant factor, in particular for low density leadframe applications.

In an embodiment, the method comprises mounting a plurality of electronic components on assigned parts of the adhesive base structure, and dissolving said parts of the base structure by irradiating said parts to thereby release said electronic components by dissipating corresponding portions of the adhesive base structure, in particular simultaneously or one after the other. By selectively irradiating only a single or a group of electronic components by electromagnetic radiation, only the irradiated subgroup of electronic components will be selectively released by dissipating one or more corresponding portions of the adhesive base structure, whereas all remaining non-irradiated electronic components will remain adhering on the adhesive base structure. This allows to precisely define one or more electronic components to be released at a time.

In an embodiment, the method comprises dissolving said at least part of the base structure so that the base structure is transferred from a component-carrying solid state into a component-releasing dissolved gaseous and/or liquid state. Hence, the state of aggregation of the base structure material may be changed-preferably triggered by an irradiation with electromagnetic radiation-which may cause the adhesive base structure to vanish from an interface between electronic component and a temporary carrier. Hence, the process of dissolving may not only convert the adhesive base structure from an adhesive into a non-adhesive configuration but may convert it from a solid into a gaseous or liquid phase thereby promoting release of an assigned electronic component in a precisely definable and quick way.

In an embodiment, the method comprises irradiating the base structure with an electromagnetic radiation source configured as a laser to thereby release the electronic component. Advantageously, a laser beam may be capable of applying a huge amount of energy in a short time to a spatially precisely definable portion of the adhesive base structure. Moreover, a laser may have a precisely defined wavelength which may be adjusted to a value at which laser-triggered dissipation of base structure material works efficiently or even best. Thus, a laser may be a preferred choice for an electromagnetic radiation source triggering dissipation of adhesive base structure material.

In an embodiment, the method comprises aligning a mutual position between, on the one hand, a carrier for carrying the electronic component and, on the other hand, the released electronic component (for instance falling downwardly by gravity), so that the released (for instance downwardly falling) electronic component is transferred and lands on the carrier. When a temporary carrier having a bottom surface on which an electronic component adheres by an adhesive base structure is subjected to an impact dissipating said adhesive base structure, the trajectory of the (for instance dropping) released electronic component is precisely predictable by physical laws. Consequently, a carrier may be arranged at a position directly beneath the previously adhering electronic component for ensuring that the (for instance dropping) released electronic component will automatically land on the carrier. Hence, a die assembly process may be triggered by a mere spatially selective irradiation in combination with a matching spatial alignment between electronic component and carrier. As a result, the process of mounting an electronic component on the carrier may be significantly simplified compared with conventional approaches. There are different embodiments for transferring the released electronic component. As mentioned, transferring the released electronic component may be accomplished by triggering the electronic component to fall downwardly by gravity. However, it is also possible in other embodiments, that transferring the released electronic component is accomplished by gas pressure, gravity or expansion of the base structure (for instance glue) or of an intermediate layer. In all these embodiments, transferring the released electronic component may be accomplished so that the transferred electronic component lands on the receiving carrier. Correspondingly, the equipment may be configured so that the released electronic component is falling downwardly by gravity so that the downwardly falling electronic component lands on the carrier. Additionally or alternatively, the equipment may be configured so that the released electronic component is transferred to land on the carrier by gas pressure, or by gravity or expansion of the base structure or of an intermediate layer.

In an embodiment, the method comprises dissolving the at least part of the base structure while the electronic component is located at a bottom side of the adhesive base structure. In such a geometry, the electronic component will automatically drop downwardly after release under the force of gravity. No further measure needs to be taken for a process of mounting the electronic component on the carrier located beneath.

In another embodiment, the method comprises dissolving the at least part of the base structure while the electronic component is located at a top side of the adhesive base structure. In such a configuration, the electronic component will not drop downwardly but will still be carried in a now non-adhesive way on the temporary carrier beneath the electronic component. Hence, after dissolving a portion of the adhesive base structure in between, the electronic component is now in a configuration in which it can be freely detached from the temporary carrier with low force. This can be accomplished for example by a vacuum suction tool or by a mechanical gripper.

In an embodiment, the method comprises, after the dissolving, picking the electronic component at one side thereof by a picking tool, in particular a suction-type picking tool, and subsequently placing the picked electronic component on a carrier. For example, the side of the electronic component which was previously attached to the now dissolved adhesive base structure may be connected with a destination surface, such as a carrier.

In an embodiment, the method comprises, after the picking (for instance by a first picking tool), further picking (for example by a second picking tool) the electronic component at an opposing other side thereof by another picking tool, in particular another suction-type picking tool, and subsequently placing the electronic component with said one side on the carrier. For certain applications, it may be desired that a target main surface of the electronic component which has been facing away from another main surface on the now dissipated adhesive base structure shall be brought in direct physical contact with a destination surface such as a carrier. In order to achieve this, two picking tools may cooperate accordingly. A first picking tool may pick the electronic component at its target main surface from the temporary carrier after having dissipated the previously adhesive base structure. Thereafter, a second picking tool may pick the picked electronic component at the other main surface to thereby expose it at its target main surface. The second picking tool may then attach the electronic component with its target main surface to a destination surface, such as a carrier.

In another embodiment, the method comprises, before the picking, attaching the electronic component at an opposing other side to a temporary carrier, and, after the picking, placing the picked electronic component with said other side on the permanent carrier. For example, it may be possible to implement an additional temporary carrier on which an electronic component may be placed for exposing a target main surface thereof for subsequent connection with a destination surface such as a carrier. Advantageously, such a re-mounting using two temporary carriers may render the need of a second picking tool dispensable.

In an embodiment, the method comprises dissolving the at least part of the base structure by irradiating with electromagnetic radiation to thereby release a plurality of electronic components to transfer the plurality of electronic components to a further carrier with changed, for example increased, pitch compared with another pitch of the plurality of electronic components on the temporary carrier. Correspondingly, the equipment may be configured for controlling irradiation of at least the mounting portion of the adhesive base structure with electromagnetic radiation to thereby release a plurality of electronic components from the mounting portion to transfer the plurality of electronic components to the carrier with changed, in particular increased, pitch compared with another pitch of the plurality of electronic components on the temporary carrier. Advantageously, the described transfer may adapt a pitch (i.e. mutual center-to-center distances between adjacent electronic components or corresponding functional portions thereof) between electronic components as separated from a common wafer and the electronic components to be assembled on a permanent carrier (such as a respective leadframe structure).

In an embodiment, the further carrier is a further temporary carrier. Preferably, the further carrier is a high temperature resistant carrier, for example is temperature resistant at least up to 220° C. For this purpose, the further carrier may be a metal carrier. Thus, the further carrier may be a temperature resistant carrier (such as a metal plate) which may withstand a subsequent high temperature processing, for instance by diffusion soldering of the electronic components on the one or more permanent carriers. The further carrier may be removed before completing manufacture of the packages.

In an embodiment, the method comprises arranging a soft and sticky layer between the plurality of electronic components and the further carrier. Preferably, the soft and sticky layer is a high temperature resistant layer, for example is temperature resistant at least up to 220° C. Said soft and sticky layer may be adhesive on both sides and may be removable without residues remaining on the electronic components. The soft and sticky layer may be configured for withstanding diffusion soldering temperature without damage.

In an embodiment, the aforementioned carrier being a high temperature resistant carrier and being covered by a high temperature resistant soft and sticky layer may form part of the equipment.

In an embodiment, the method comprises transferring the plurality of electronic components from the further carrier to one or more permanent carriers, in particular by batch diffusion soldering (i.e. connecting the electronic components with the at least one permanent carrier by simultaneously diffusion soldering) and/or under application of pressure and heat. For example, the permanent carriers may be different leadframe structures of a leadframe. Such a leadframe structure may comprise a die pad for accommodating one electronic component (or a plurality of electronic components) and may comprise at least one lead section comprising one or more leads. However, other types of permanent carriers, such as a DCB (Direct Copper Bonding) substrate, a DAB (Direct Aluminum Bonding) substrate, an AMB (Active Metal Brazed) substrate, an IMS (Insulated Metal Substrate), a PCB (printed circuit board), etc., may be possible as well. A solder layer comprising a solder material for carrying out diffusion soldering (or another type of soldering) may be pre-formed on the respective permanent carrier and/or on one or more pads of the respective electronic component.

In an embodiment, the mentioned solder material comprises tin or a tin alloy, in particular at least one of the group consisting of AgSn, AuSn, NiSn, CuSn, AgCuSn, and InSn. Tin may have excellent solder properties. At least one additional metallic constituent may refine the properties of the solder material. The mentioned solder materials may be used for diffusion soldering.

In an embodiment, the solder material has a thickness in a range from 5 μm to 100 μm, in particular in a range from 10 μm to 50 μm. Thus, diffusion soldering may promote a compact design of the obtained packages.

In an embodiment, the method comprises mounting the electronic component on the adhesive base structure on an optically transparent temporary carrier, and irradiating at least part of the base structure with electromagnetic radiation through the optically transparent temporary carrier, for dissolving the base structure. Hence, it may be possible to connect the electronic component(s) by an adhesive base structure on a temporary carrier which is optically transparent for electromagnetic radiation capable of dissipating the adhesive base structure. The electromagnetic radiation triggering dissipation of the adhesive base structure may then propagate through the temporary carrier for reaching the adhesive base structure to be destructed by said radiation. The described geometry may increase the reliability of the dissipation and release process, since it may be ensured that the entire connection surface between temporary carrier and electronic component may be reached by the electromagnetic radiation beam.

In an embodiment, the method comprises irradiating the base structure by scanning the base structure by an electromagnetic radiation source. Said scanning may be accomplished by moving, on the one hand, the electromagnetic radiation source and/or an electromagnetic radiation beam thereof (for instance by tilting a reflection mirror) and, on the other hand, the base structure relative to each other. Hence, a relative motion between, on the one hand, the temporary carrier with the electronic component(s) and the adhesive base structure in between, and, on the other hand, the electromagnetic radiation source (such as a laser device) or its beam (such as a laser beam) may be adjusted. By this mutual motion, it may be ensured that the electromagnetic radiation beam scans a predefined trajectory on the adhesive base structure to thereby dissipate adhesive base structure material in a precisely definable manner. For instance, a temporal order may be defined according to which the electronic components are forced to drop downwardly by gravity after dissipation of previously adhesive base structure material thereof.

In an embodiment, the method comprises irradiating the base structure through a partially optically transparent and partially opaque mask arranged between the base structure and the electromagnetic radiation source. In such a configuration, the electromagnetic radiation will be allowed to pass through the optically transparent part(s) of the mask only, but not through the opaque portion(s). This may allow to use an electromagnetic radiation source emitting light over a broad spatial range. Irradiated portions may be defined by the mask design.

In particular, said mask may be embodied as a greyscale mask configured for irradiating a portion of the base structure corresponding to an edge of the electronic component with higher intensity than another portion of the base structure corresponding to a center of the electronic component. In other words, the optically transparent portion of the mask may have a greyscale profile allowing different amounts of light to pass through different portions of the optically transparent portion. For instance, a dark grey portion may allow to pass less light than a light grey portion. Advantageously, an edge region of a transmissive window in the mask may be configured to allow more light transfer than a central region of the transmissive window. This may allow to render the release process most efficient along a perimeter of the electronic component. It has been found that the release process can be made particularly reproducible and precise when starting the dissolving process of the adhesive base structure from the perimeter of the electronic component.

In an embodiment, the method comprises thinning and thereafter separating a wafer into a plurality of electronic components while the wafer is arranged on the adhesive base structure. Thus, the adhesive base structure on a temporary carrier may keep the wafer and its individual electronic components fixed in place during a singulating or dicing process. For instance, said separation may be accomplished by mechanical dicing (for instance using one or more cutting blades), laser dicing (for example by using at least one laser beam) and/or dicing by etching (for instance plasma dicing). Also a previous wafer thinning process (for instance accomplished by grinding) may be carried out while the wafer is attached to a temporary carrier by an adhesive base structure. After thinning and separating, the adhesive base structure may be dissipated (in particular in a spatially resolved way) for releasing the thinned and separated electronic components.

In an embodiment, the method comprises, after the thinning and before the separating, forming pads on a thinned surface of the wafer. Hence, pads (such as electrically conductive terminals) may be formed on the thinned wafer still on wafer level. This may be accomplished by a metal deposition and patterning process.

In an embodiment, said equipment comprises the adhesive base structure which is configured for dissolving and therefore being removed when being irradiated with electromagnetic radiation. For example, the adhesive base structure may be a glue which can be evaporated by a laser beam. Such a configuration may be preferred, since the adhesive base structure may be gone after the dissipation process and may therefore release the electronic component(s).

In another embodiment, said equipment comprises the adhesive base structure which is configured for being converted from an adhesive state into a non-adhesive or less adhesive state when being irradiated with electromagnetic radiation. Thus, it is possible that the adhesive base structure is made of a material which is chemically converted into a less on non-adhesive configuration by the impact of light. For instance, release may then be achieved by a conversion of the adhesive base structure into a configuration in which its adhesive force is below its force of gravity, so that the electronic component will simply fall downwardly without taking any further measure.

In an embodiment, the electromagnetic radiation source comprises a laser. This has the advantage that wavelength and spatial range of impact may be precisely selected to ensure release of the electronic component in a very accurate and definable way. Also the high-power of a laser beam may be of utmost advantage for the mentioned purpose.

In an embodiment, the alignment unit is configured for statically placing the vertically downwardly falling electronic component in lateral alignment with the statically placed carrier so that the vertically downwardly falling electronic component lands on the carrier (in particular being static during the falling). Such a configuration is shown in FIG. 1. The released electronic component will simply move downwardly under the force of gravity and will reach the carrier without taking any further measure.

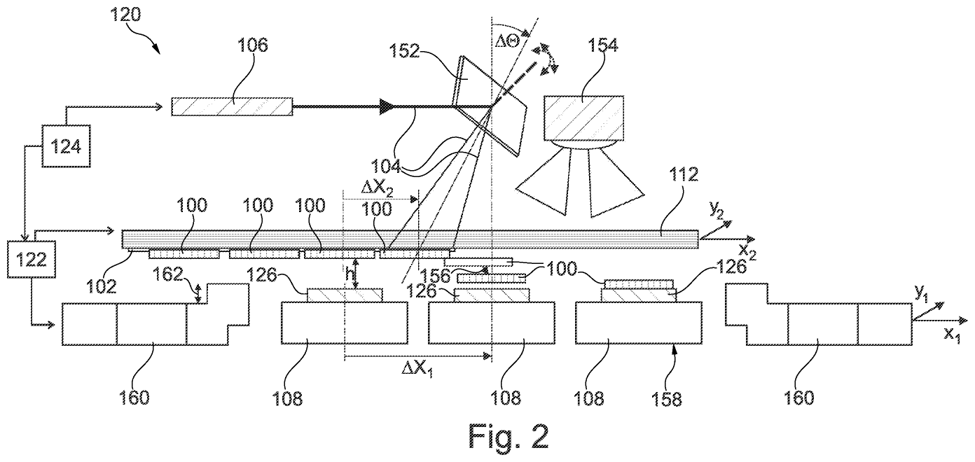

In another embodiment, the alignment unit is configured for dynamically moving the electronic component and the carrier relatively to each other along a lateral direction transverse to gravity so that the downwardly falling electronic component lands on the carrier under consideration of said lateral motion (in particular during the falling). Such a configuration is shown in FIG. 2. In such an embodiment, it is for instance possible that the electronic component moves horizontally and the carrier rests, or vice versa, so that the released electronic component may have motion trajectories both in horizontal and vertical directions and/or so that the carrier may move horizontally. The relative carrier-component positioning may be adjusted under consideration of motion components of the electronic component and/or the carrier.

In an embodiment, the equipment comprises a control unit configured for controlling the electromagnetic radiation source for executing said irradiating and the alignment unit for executing said aligning. For instance, such a control unit may be a processor coordinating the functionality of the mentioned constituents of the system. For example, such a control unit may be controlled by a software program.

In an embodiment, the equipment comprises the carrier which comprises an adhesive medium on a main surface at which the landing electronic component will be stopped. The dropped electronic component may preferably adhere to the adhesive medium. For example, the adhesive medium may comprise at least one of adhesive solder paste, adhesive sinter paste, and glue. When a released electronic component drops as a result of the loss of an adhesion force by the dissipated adhesive base structure and reaches the carrier, the adhesive medium thereon will cause the downwardly falling electronic component to stop and remain adhering on the adhesive medium. When configuring said adhesive medium as adhesive solder paste, adhesive sinter paste, or the like, the obtained configuration is directly ready for permanent connection between carrier and electronic component, for instance by soldering or sintering. Thus, a die assembly process may be rendered significantly more efficient by exemplary embodiments.

Said adhesive medium may also be denoted as sticky mediator. The adhesive medium may be a sticky paste which may be directly subjected to soldering or sintering. It is also possible that the adhesive medium is a sticky paste which is applied on a (for example sputtered) layer of diffusion solder on the carrier. Such a sticky paste may be volatile when connecting the dropped electronic component with the carrier by diffusion soldering, which may involve temperatures above 200° C.

In an embodiment, the equipment comprises the electronic component having pads on both opposing main surfaces and/or experiencing vertical current flow during operation. For instance, the electronic component may be a field effect transistor chip having a drain pad on one main surface and having both a source pad and a gate pad on the other main surface. Such a device may have a vertical current flow when active.

In an embodiment, a thickness of the electronic component may be in a range from 5 μm to 100 μm, in particular in a range from 10 μm to 60 μm. Such very thin electronic components, in particular semiconductor chips, may be particularly prone to damage in conventional needle-assisted release processes, in particular due to the phenomenon of die knocking. However, a laser-assisted release process according to an exemplary embodiment may eliminate the phenomenon of die knocking.

In an embodiment, the electronic component is configured as a power semiconductor chip. Thus, the electronic component (such as a semiconductor chip) may be used for power applications for instance in the automotive field and may for example have at least one integrated insulated-gate bipolar transistor (IGBT) and/or at least one transistor of another type (such as a MOSFET, a JFET, a HEMT, etc.) and/or at least one integrated diode. Such integrated circuit elements may be manufactured for instance in silicon technology or based on wide-bandgap semiconductors (such as silicon carbide, gallium nitride). A semiconductor power chip may comprise one or more field effect transistors, diodes, inverter circuits, half-bridges, full-bridges, drivers, logic circuits, further devices, etc.

In an embodiment, the package is configured as power package. A power package may be a package comprising at least one power chip as electronic component. Thus, the package may be configured as power module, for instance molded power module such as a semiconductor power package. For example, an exemplary embodiment of the package may be an intelligent power module (IPM). Another exemplary embodiment of the package is a dual inline package (DIP).

In an embodiment, the package comprises an encapsulant encapsulating at least part of the electronic component. In the context of the present application, the term “encapsulant” may particularly denote a substantially electrically insulating material surrounding at least part of an electronic component and part of a carrier to provide mechanical protection, electrical insulation, and optionally a contribution to heat removal during operation. In particular, said encapsulant may be a mold compound. A mold compound may comprise a matrix of flowable and hardenable material and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel).

In an embodiment, the package comprises at least one electrically conductive coupling element electrically coupling the electronic component with the carrier (in particular with a die pad and/or with at least one lead). Such an electrically conductive coupling element may be a clip, a bond wire or a bond ribbon. A clip may be a curved electrically conductive body accomplishing an electric connection with a high connection area to an upper main surface of a respective electronic component. Additionally or alternatively to such a clip, it is also possible to implement one or more other electrically conductive interconnect bodies in the package, for instance a bond wire and/or a bond ribbon connecting the electronic component with the die pad and/or a lead or connecting different pads of an electronic component.

For example, a package according to other exemplary embodiments may be configured as one of the group consisting of a leadframe connected power module, a Control integrated power system (CIPOS) package, a Transistor Outline (TO) package, a Quad Flat No Leads Package (QFN) package, a Small Outline (SO) package, a Small Outline Transistor (SOT) package, and a Thin Small Outline Package (TSOP) package. Also packages for sensors and/or mechatronic devices are possible embodiments. Moreover, exemplary embodiments may also relate to packages functioning as nano-batteries or nano-fuel cells or other devices with chemical, mechanical, optical and/or magnetic actuators. Therefore, the package according to an exemplary embodiment is fully compatible with standard packaging concepts and appears externally as a conventional package, which is highly user convenient.

In an embodiment, at least one further electronic component in mounted on the carrier. Thus, a plurality of electronic components, which may each be released from an adhesive base structure, may be mounted side by side on the same carrier. For instance, at least two electronic components may be mounted on one carrier. This may allow to realize even complex or sophisticated electronic functionality.

As substrate or wafer forming the basis of the electronic components, a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages of the present invention will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

Conventionally, pick and place processes are executed to peel known good dies from a dicing tape by pushing a needle from the back side in a center part. As a result, the tape starts to peel off from the corners of the die. However, this may cause adjacent dies to abut to each other. This phenomenon, which is called die knocking, can cause severe damage to the die. For example, a small radius can cause indentations and/or cracks.

Furthermore, delamination of the dies from the tape may take a significant amount of time with the described conventional approach.

Moreover, the risk of die knocking may make it necessary to establish a large safety edge zone around an active area. This may lead, in turn, to a reduced active area. Thus, no significant area usage improvement is conventionally possible due to die nocking effect. Die knocking at die pick-up due to needle eject phenomena may require defined distances of adjacent dies to avoid damage. A minimum distance between active areas of dies may be 90 μm-including the above-mentioned safety region. Typical values of a distance between active areas of dies may be even above 100 μm.

The issues involved by die knocking may be even more severe for small kerf technologies like plasma dicing. Plasma dicing may reduce the damage to the bulk material compared to mechanical sawing. Furthermore, as a result plasma dicing may create a very narrow kerf width (typically smaller than 10 μm), so that the above-mentioned safety regions may be insufficient in such a scenario.

Concluding, needle based die release can cause damage and may afford counter measures impacting units per hour and effort for chip design and manufacture.

According to an exemplary embodiment of a first aspect, an electronic component is attached to a temporary carrier via an adhesive base structure. The attached electronic component may be separated from the temporary carrier by dissolving sacrificial material of the base structure. By dissolving, the previously adhesive base structure may be locally removed (for instance evaporated). For example, this removal, dissipation or dissolving can be triggered by electromagnetic radiation, by heat or chemically. Upon releasing the electronic component from the previous adhesive base structure, the released electronic component may drop without taking any further measure by the force of gravity and may land on a spatially aligned carrier beneath. Thus, the release process may already properly prepare an assembly of the falling electronic component on the carrier beneath. By dissolving the adhesive base structure, the adhesive force thereof may vanish, which may cause the electronic component to fall downwardly. This may make it possible to handle electronic components efficiently.

According to an exemplary embodiment of a second aspect, an adhesive base structure with attached electronic component is selectively irradiated with electromagnetic radiation for triggering release of the electronic component from the adhesive base structure. This may allow a pick and place unit to pick the released electronic component at one side and to further pick the picked electronic component at an opposing other side for placing the electronic component on a carrier. After the further picking process, the initially used picking tool may be removed from the electronic component. Selective irradiation of an adhesive base structure with electromagnetic radiation may cause a loss of an adhesive holding force which enables a pick and place unit having at least two picking tools for handling the electronic components at both sides for putting it with a desired main surface onto a destination surface, such as a permanent carrier. This architecture may allow to assemble the electronic component on the carrier in a very simple and reliable way and to handle electronic components efficiently.

According to an exemplary embodiment of a third aspect, a preform of an electronic component is attached on one side to a temporary carrier. Furthermore, the electronic component may be attached at an opposing other side to a further temporary carrier. Thereafter, the initial temporary carrier may be removed from the electronic component. By irradiating an adhesive base structure between the further temporary carrier and the electronic component with electromagnetic radiation, the electronic component can be released from said adhesive base structure. This may make it possible to then pick the electronic component and place it on a destination surface, such as a permanent carrier. Such an approach may make it possible to assemble the electronic component on the carrier in a very simple and reliable way and to handle electronic components efficiently.

According to different embodiments, a reduced chip edge safety area may be enabled by a pick and place architecture with laser assisted die release. Advantageously, die picking may be carried out without needle eject, but for example in a laser assisted way. A correspondingly manufactured electronic component (such as a semiconductor chip) may be formed with ultra-small edge safety area. For example, such a safety edge zone of an electronic component according to an exemplary embodiment may be less than 90 μm, for instance may be in a range from 70 μm to below 90 μm, for example below 80 μm. For instance, a safety edge zone may extend as a circumferentially closed edge structure extending around an entire perimeter of an active region of the electronic component. Preferably, such an electronic component may be singulated from a wafer compound by plasma dicing or chemical etching or laser dicing at its edge. After singulation, such an electronic component may be transferred by a laser assisted pick and place process in which die-knocking is being avoided inherently. Hence, a gentle way of executing die picking for thin and fragile dies may be provided. Furthermore, a reduced non-used edge area may be made possible.

FIG. 1 illustrates an equipment 120 according to an exemplary embodiment. Descriptively speaking, FIG. 1 shows a direct dynamic release process.

The illustrated equipment 120 comprises an electromagnetic radiation source 106 embodied as laser source. The electromagnetic radiation source 106 is configured for irradiating a mounting portion 150 of an adhesive base structure 102 with electromagnetic radiation 104. For example, the emitted beam of electromagnetic radiation 104 may be ultraviolet (UV) light configured for dissolving material of adhesive base structure 102 which will be described below in further detail. For example, the UV light may be pulsed laser light of a wavelength of 265 nm. It is also possible that the UV light generated by electromagnetic radiation source 106 has a wavelength of 355 nm. More generally, the electromagnetic radiation source 106 may be a laser source configured for emitting a pulsed or continuous laser beam. The generated beam of electromagnetic radiation 104 may be directed on a reflection mirror 152 from where the electromagnetic radiation 104 is reflected towards an optically transparent temporary carrier 112. The optically transparent temporary carrier 112 may have a diameter in a range from 8 inches to 20 inches, for instance may have a diameter of 12 inches. The optically transparent temporary carrier 112 may be a glass plate. The beam of electromagnetic radiation 104 propagates through the optically transparent temporary carrier 112. On the back side of the optically transparent temporary carrier 112, i.e. on the main surface of the optically transparent temporary carrier 112 facing away from the impinging beam of electromagnetic radiation 104, a plurality of electronic components 100 are mounted. More precisely, the electronic components 100 are mounted on the optically transparent temporary carrier 112 by an adhesive base structure 102 in between.

The electronic components 100 may be semiconductor chips which have been singulated from a previously integral wafer by dicing. For instance, the electronic components 100 may be power semiconductor chips. For example, each of the electronic components 100 may comprise at least one monolithically integrated circuit element, such as a field effect transistor (for example a metal oxide semiconductor field effect transistor, MOSFET, a junction field effect transistor, JFET), a diode, etc. A vertical thickness, d, of the electronic components 100 may be below 100 μm, for example in a range from 20 μm to 80 μm, for instance 50 μm. An area of a main surface of the electronic components 100 may be in a range from 1 mm² to 35 mm².

In the shown embodiment, the adhesive base structure 102 is a continuous layer of solid or viscous adhesive by which the electronic components 100 are held on a bottom main surface of the optically transparent temporary carrier 112. In the shown embodiment, the adhesive base structure 102 is a continuous layer covering main surfaces of all electronic components 100 and sections in between. Alternatively, the adhesive base structure 102 may be formed of a plurality of unconnected islands, each for holding a respective electronic component 100 on the optically transparent temporary carrier 112 by an adhesive force.

The above-mentioned electromagnetic radiation source 106 in combination with the reflective mirror 152, an alignment camera 154 (configured for aligning and inspecting) and a control unit 124 constitute a scanner for scanning the component holding main surface of the optically transparent temporary carrier 112. The scanner may scan the temporary carrier 112 along a predefined or definable trajectory. Such a trajectory may for instance be a meander trajectory, a spiral trajectory, etc. In other words, said scanner may selectively irradiate a certain surface portion of the temporary carrier 112 including the adhesive base structure 102 thereon with electromagnetic radiation 104. Thus, it may be possible to irradiate the base structure 102 by scanning the base structure 102 by a beam of electromagnetic radiation 104 emitted by the electromagnetic radiation source 106. This may be accomplished by moving, on the one hand, the electromagnetic radiation source 106 and/or the beam of electromagnetic radiation 104 and, on the other hand, the base structure 102 relative to each other. For instance, the reflection mirror 152 may be tilted for moving the beam of electromagnetic radiation 104 impinging on the adhesive base structure 102. This may lead to a relative motion between the beam and the base structure 102, and consequently to a scanning.

Advantageously, the combination of the attributes of the adhesive base structure 102 and the laser light may ensure that the adhesive base structure 102 is dissolved and dissipates when being irradiated with the laser light of sufficient intensity and appropriate wavelength. In this context, dissolving may mean a dissipation, removal or evaporation of the adhesive base structure 102 or part thereof which therefore vanishes in portions irradiated with the laser light. The adhesive base structure 102 may be made of a UV sensitive adhesive. For example, irradiating such an adhesive base structure 102 with UV light may convert the material of the adhesive base structure 102 into carbon dioxide, aqueous vapor, nitrogen gases, etc. In the shown embodiment, the scanner scans one mounting portion 150 of adhesive base structure 102 with the electromagnetic radiation 104 and therefore removes the adhesive base structure 102 selectively in the mounting portion 150. By selectively irradiating the mounting portion 150, the electronic component 100 which has been previously held thereon by adhesion is released from the mounting portion 150 and therefore drops downwardly by the force of gravity, see reference sign 156.

As shown as well in FIG. 1, a plurality of permanent carriers 108, each for carrying a respective electronic component 100 for forming a respective package 158, are arranged beneath the electronic components 100 being attached on the temporary carrier 112. For example, the carriers 108 can be embodied as leadframe structure forming part of a common leadframe. Such carriers 108 may be metal plate sections, for instance made of copper. For instance, a copper leadframe may be used for forming the carriers 108 and may have a size of up to 100×300 mm². As an alternative to leadframe-type carriers 108, other embodiments may also use laminate-type permanent carriers 108, etc.

Referring again to the equipment 120, it comprises an alignment unit 122 for aligning a mutual position between, on the one hand, a respective permanent carrier 108 for carrying a respective electronic component 100 and, on the other hand, the released electronic component 100 falling downwardly by gravity, so that the downwardly falling electronic component 100 lands on the assigned carrier 108. The alignment unit 122 may make use, for the purpose of aligning, of index holes 160 and/or up-set structures 162 of the leadframe. As shown, the alignment unit 122 may be controlled by control unit 124 and may ensure a correct mutual spatial relationship between a laser-released downwardly falling electronic component 110 and the assigned carrier 108. The illustrated control unit 124, for instance a processor or a control computer, may be configured for controlling the electromagnetic radiation source 106 for executing said irradiating and the alignment unit 122 for executing said aligning. For instance, the alignment unit 122 may force the temporary carrier 112 and/or the array of carriers 108 to move forwardly (for instance towards the right hand side of FIG. 1) after the electromagnetic radiation source 106 has released a respective electronic component 100 from the temporary carrier 112 and the dropped electronic component 100 has landed on an assigned carrier 108. Thereafter, this procedure may be repeated with the next electronic component 100 and carrier 108.

According to FIG. 1, the alignment unit 122 is configured for statically placing the vertically downwardly falling electronic component 100 in lateral alignment with the statically placed carrier 108 so that the vertically downwardly falling electronic component 100 lands on the static carrier 108. Thus, the alignment unit 122 may adjust a mutual alignment between carrier 108 and electronic component 100 with regard to a vertical optical axis 164 by moving carrier 108 and/or electronic component 100 horizontally only prior to a release process. During the release process, carrier 108 and electronic component 100 may remain at a static position in horizontal direction. After the release process, carriers 108 and/or electronic components 100 may be moved horizontally for aligning a next pair of carrier 108 and electronic component 100 with respect to the beam of electromagnetic radiation 104.

As an alternative to the sequential release of individual electronic components 100 from the base structure 102, it may also be possible to adapt the electromagnetic radiation-based release so that a group of electronic components 100 is released simultaneously from the adhesive base structure 102 by irradiating them together by electromagnetic radiation 104.

Now referring in further detail to the process of forming a package 158, FIG. 1 shows that each carrier 108 has an adhesive medium 126 on a top main surface at which the landing electronic component 100 will be stopped. Said adhesive medium 126 may comprise for example an adhesive solder paste. When a released electronic component 100 lands on an assigned carrier 108, it will be forced to remain on the carrier 108 by the sticky adhesive medium 126. After that, the carrier-component-adhesive medium arrangement may be subjected to soldering for forming a permanent solder connection between carrier 108 and electronic component 100 by adhesive medium 126 made of a solderable material. For instance, the adhesive medium 126 may be a sticky paste which may have a thickness of for instance 80 μm to 120 μm.

Thereafter, one or more electric connections of the electronic component 100 may be established, for instance using electrically conductive connection structures such as at least one bond wires and/or clip (not shown). The electronic component 100 and the carrier 108 as well as the medium 126 and the optional electrically conductive connection structure may then be subjected to encapsulation, for instance molding. Thereafter, the individual packages 158 may be separated from the leadframe compound.

By taking the described measures, a very simple treatment of the electronic components 100 may be made possible without the risk of damage. To put it shortly, a direct transfer of electronic components 100 to a carrier 108 may be achieved. In particular, no pick and place configuration using a needle for lifting electronic components 100 from a back side are required. Hence, issues related to die knocking may be overcome. In contrast to this, chip release may be accomplished in a laser-assisted way by selectively dissolving portions of an adhesive base structure 102 to thereby release individual electronic components 100 using the force of gravity.

As already mentioned, the adhesive base structure 102 may be configured for dissolving when being irradiated with UV electromagnetic radiation 104. Electromagnetic radiation 104 of another wavelength may be used, for instance visible light and/or infrared light. It is also possible that another trigger for dissolving the adhesive base structure 102 is implemented, for instance heat or a chemical treatment. In the described preferred embodiment, however, the adhesive base structure 102 is configured for being converted from an adhesive solid or viscous state into a gaseous state so that it vanishes from the interface between temporary carrier 112 and electronic component 100 when being irradiated with the electromagnetic radiation 104. Hence, rather than being converted from an adhesive configuration into a less adhesive configuration, the adhesive base structure 112 of FIG. 1 may be entirely removed between temporary carrier 112 and electronic component 100. This may render the release process fast, accurate and highly reproducible.

In order to process electronic components 100 of different types with the same equipment 120, it may be possible to adjust an adaptive exposure pattern. A vertical distance, h, between the adhering electronic components 100 and the top side of the adhesive medium 126 may be adjusted appropriately and depending on an application. The coordinate systems x1, y1 of the permanent carriers 108 and the coordinate systems x2, y2 of the temporary carrier 112 may be adjusted by the alignment unit 122. A motion dimension ΔX1 of the permanent carriers 108 and a motion dimension ΔX2 of the temporary carrier 112 after each located dissipation process may also be adjusted by the alignment unit 122.

FIG. 2 illustrates an equipment 120 according to an exemplary embodiment. Descriptively speaking, the embodiment of FIG. 2 implements a direct dynamic release process with on-the-fly transfer.

The equipment 120 according to FIG. 2 differs from the equipment 120 according to FIG. 1 in particular in that, according to FIG. 2, the alignment unit 122 is configured for dynamically moving the electronic components 100 and the carriers 108 relatively to each other along a lateral direction (which is here a horizontal direction) transverse (which is here perpendicular) to gravity (which is effective along a vertical direction). This is accomplished so that the downwardly falling electronic component 100 lands on the carrier 108 under consideration of said lateral motion, i.e. has a vertical and a horizontal motion component during falling. Hence, the optically transparent temporary carrier 112 may be moved horizontally towards the right-hand side of FIG. 2 also during the irradiation, release and/or falling process. As a result, a dropping electronic component 100 being released from the temporary carrier 112 by UV radiation may thus move along an inclined trajectory rather than purely vertically, as shown by reference sign 156 in FIG. 2. The alignment unit 122 can consider horizontal and vertical motion components of a falling electronic component 100 for correctly positioning the assigned carrier 108 with respect to said electronic component 100.

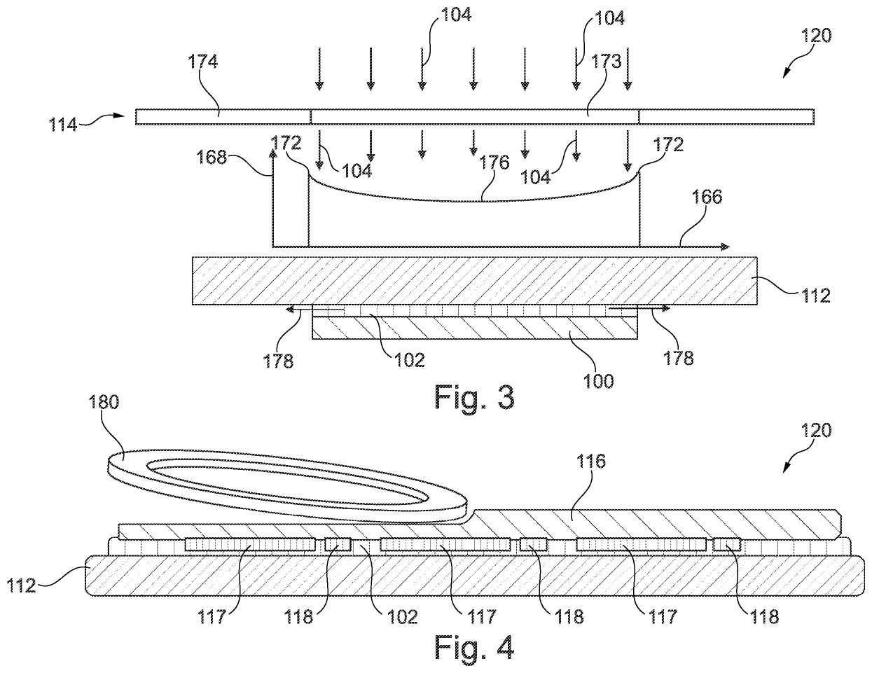

FIG. 3 illustrates an equipment 120 according to another exemplary embodiment. While FIG. 1 and FIG. 2 show embodiments in which a spatially confined laser beam dynamically scans an adhesive base structure 102 for dissolving or dissipating it for releasing electronic components 100, FIG. 3 shows an embodiment in which a mask 114 is used in combination with a spatially broad illumination by UV light.

According to FIG. 3, the adhesive base structure 102 is irradiated with UV light through a partially optically transparent and partially opaque mask 114 which is arranged between the light-sensitive adhesive base structure 102 and the light-emitting electromagnetic radiation source 106 (the latter is not shown in FIG. 3 and emits the impinging electromagnetic radiation 104). According to FIG. 3, mask 114 is embodied advantageously as a greyscale mask which is configured for irradiating a portion of the base structure 102 connected to an edge of the electronic component 100 with higher intensity than another portion of the base structure 102 connected to a center of the electronic component 100. To put it shortly, FIG. 3 illustrates an alternative exposure concept which is based on grey scale lithography.

More specifically, FIG. 3 shows a diagram having an abscissa 166 along which a spatial coordinate corresponding to the horizontal extension of the adhesive base structure 102 is plotted. Along an ordinate 168, an irradiation intensity is plotted indicating an electromagnetic radiation intensity according to which the respective spatial portion of the adhesive base structure 102 is irradiated with UV light due to the spatially dependent optical transmissivity characteristic of the transmissive section 173 of mask 114 delimited by opaque sections 174. As can be taken from the plotted diagram, the optical transmissivity of the transmissive section 173 has a maximum at edges 172 and has a minimum in a central portion 176 of the adhesive base structure 102. As a result, the process of UV-triggered dissolving or dissipation of the adhesive base structure 102 will start at the circumferential edge of the adhesive base structure 102, as indicated by arrows 178. This may lead to a highly controlled decomposition of the adhesive base structure 102 starting at its edges and extending from there towards the center. This may allow, in turn, for an outgassing from the outer perimeter of the die-type electronic component 100. Advantageously, the electronic component 100 is released from the optically transparent temporary carrier 112 in a properly controllable way according to FIG. 3.

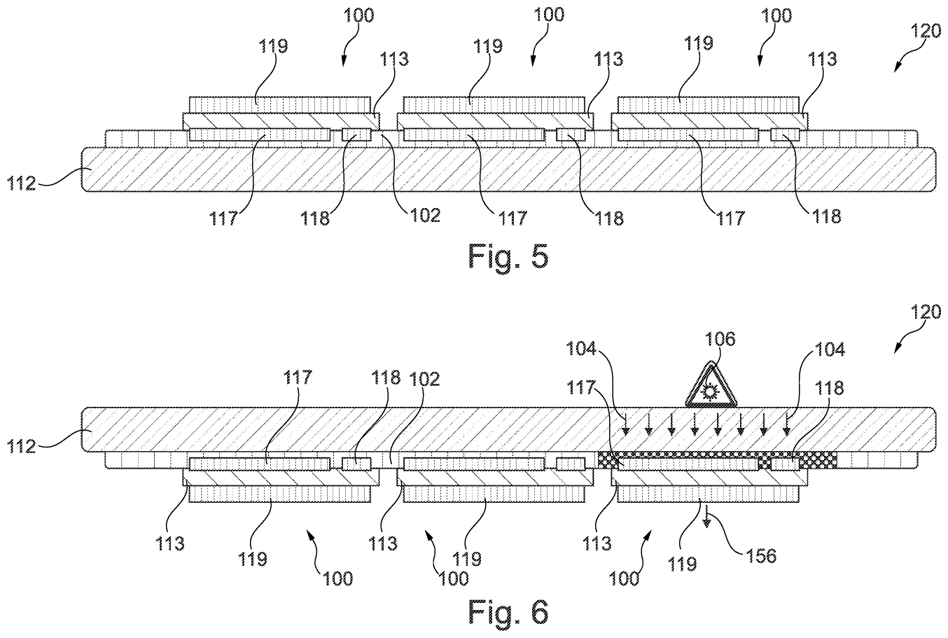

FIG. 4 to FIG. 6 show different views of structures obtained during carrying out a method according to an exemplary embodiment.

Referring to FIG. 4, a semiconductor wafer 116 is thinned by grinding using a grinding tool 180 while the wafer 116 is arranged on an adhesive base structure 102. The latter is formed, in turn, on an optically transparent temporary carrier 112. The adhesive base structure 102 may be made of a photopolymer. Optically transparent temporary carrier 112 may be for example a UV transparent carrier, for instance made of glass such as Borofloat®. For instance, wafer 116 may be a processed semiconductor wafer, for example a silicon wafer. As shown, pads 117, 118 are already formed on a bottom main surface of wafer 116 facing away from the grinding tool 180. For example, each pair of pads 117, 118 may be a source pad and a gate pad of a transistor chip which may be singulated later from the wafer 116 as respective electronic component 100.

Referring to FIG. 5, the wafer 116 has been separated into a plurality of electronic components 100 while the wafer 116 is still arranged on the adhesive base structure 102. Such a separation may be accomplished for instance by mechanically dicing, laser dicing and/or plasma dicing.

After the thinning illustrated in FIG. 4 and before the separating described above referring to FIG. 5, pads 119 may be formed on a thinned surface of the wafer 116, for instance one for each electronic component 100. For example, each pad 119 may be a drain pad of the above-mentioned transistor chip. Thus, the manufactured electronic components 100 may have a vertical current flow through semiconductor body 113 and between pads 117, 118, 119. In other words, the electronic component 100 is equipped with pads 117, 118, 119 on both opposing main surfaces and experiences vertical current flow during operation.

To put it shortly, FIG. 5 shows that wafer 116 may be subjected to back side metallization and singulation (for instance using a low kerf technology, such as plasma dicing).

Referring to FIG. 6, the structure shown in FIG. 5 has been sent to backend processing. The structure shown in FIG. 5 has been turned upside down and is now subjected to irradiation with electromagnetic radiation 104 emitted by electromagnetic radiation source 106. More specifically, only the electronic component 100 on the right-hand side of FIG. 6 is irradiated with UV light so that the assigned portion of the adhesive base structure 102 is dissipated. This causes only this electronic component 100 to drop downwardly due to a loss of adhesion, see reference sign 156. Although not shown in FIG. 6, the electronic component 100 may fall directly onto an aligned carrier 108, such as a leadframe structure, as described above referring to FIG. 1 and FIG. 2.

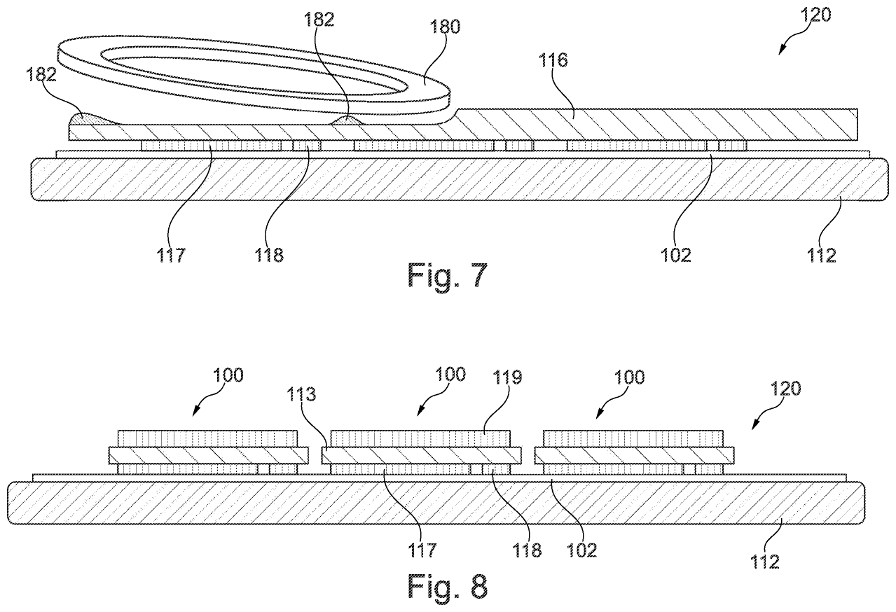

FIG. 7 to FIG. 9 show different views of structures obtained during carrying out a method according to an exemplary embodiment. To put it shortly, in particular FIG. 9 illustrates a pick and place configuration using flip tools in combination with laser-assisted release of an electronic component 100. A flip-bonder may be used for this purpose.

Referring to FIG. 7, a wafer 116 is subjected to thinning by grinding, as described referring to FIG. 4. This may lead to the formation of bulges 182. In particular when processing thin wafers 116, bulges 182 may be created during grinding as non-underfilled areas. A water-soluble resin may be used for preventing this, for instance HogoMax™. According to FIG. 7, temporary carrier 112 may be a UV transparent carrier, such as a silicon dioxide plate or a tape. Adhesive base structure 102 may be a UV adhesive (for instance having a thickness in a range from 0.5 μm to 15 μm).

A difference between FIG. 7 and FIG. 4 is that, according to FIG. 4, pads 117, 118 are embedded in the adhesive base structure 102, whereas they are arranged on top of the adhesive base structure 102 according to FIG. 7.

Referring to FIG. 8, the structure of FIG. 7 is shown after grinding, back side metallization and singulation. These processes may be carried out as described referring to FIG. 4 and FIG. 5.

For instance, when the silicon thickness of the respective electronic component 100 is approximately 40 μm, singulation may be accomplished by plasma treatment with structured copper on the back side. This may be appropriate in particular for a hard carrier. In another scenario in which the semiconductor thickness is not more than 110 μm, singulation may be carried out by laser dicing which is also compatible with a hard carrier. When the thickness of the semiconductor body is larger than 110 μm, singulation may be executed by mechanically dicing on a tape.

Referring to FIG. 9, the further handling of the electronic components 100 may be carried out while the electronic components 100 remain attached to the adhesive base structure 102 on top main surface of the optically transparent temporary carrier 112. The electronic components 100 will not fall downwardly under the force of gravity according to FIG. 9 when dissolving the adhesive base structure 102, since the electronic components 100 are mounted on the top side rather than on the bottom side of the temporary carrier 112 according to FIG. 9.

The procedure of handling the electronic components 100 is carried out by equipment 120 shown in FIG. 9. Said equipment 120 comprises electromagnetic radiation source 106, such as a laser source, configured for irradiating a mounting portion 150 of the adhesive base structure 102 on which an electronic component 100 to be released is mounted. By irradiation of the mounting portion 150 of the base structure 102 with a beam of electromagnetic radiation 104, the mounting portion 150 is destroyed and removed to thereby release the electronic component 100 from the mounting portion 150, since no adhesive force is effective any longer.

Furthermore, equipment 120 according to FIG. 9 comprises a pick and place unit 128 configured for, after the releasing, picking the electronic component 100 at one side by a picking tool 110. In the shown embodiment, picking tool 110 is a vacuum suction tool lifting the released electronic component 100 by a vacuum force in between. In the shown embodiment, the main surface of the electronic component 100 at which it is picked by the picking tool 110 corresponds to the back side metallization in form of pad 119. However, it may be desired for certain applications that the pad 119 (such as a drain pad of a transistor chip is placed on a destination surface, such as a carrier 108 (not shown in FIG. 9).

In order to accomplish this goal, the pick and place unit 128 comprises another picking tool 110′. In the described embodiment, the other picking tool 110′ is a further vacuum suction tool configured for holding the released electronic component 100 by a vacuum force in between. In FIG. 9, only one picking tool 110/110′ is shown for the sake of simplicity, but two separate picking tools 110, 110′ will be present in this embodiment. In order to render pad 119 accessible for placement on the above-mentioned target surface, the electronic component 100 may be picked by the other picking tool 110′ on its main surface having pads 117, 118 while it is still held by picking tool 110 on the main surface having pad 119. After having picked the electronic component 100 at its opposing other side by the other picking tool 110′, picking tool 110 may be removed from the electronic component 100. Subsequently, the exposed pad 119 of the electronic component 100 may be placed by the other picking tool 110′ on said target surface, for instance on a permanent carrier 108.

Summarizing, the electronic component 100 may be formed or placed on the adhesive base structure 102 on the optically transparent temporary carrier 112. The base structure 102 may then be irradiated with electromagnetic radiation 104 through the optically transparent temporary carrier 112 for dissolving the base structure 102 below the electronic component 100. Hence, part of the base structure 102 may be dissolved while the electronic component 100 is located at a top side of the adhesive base structure 102. After the dissolving, the electronic component 100 is picked at one side thereof by picking tool 110. After this picking, the electronic component 100 is further picked at an opposing other side thereof by the other picking tool 110′. Descriptively speaking, a released, detached and picked electronic component 100 is handed over from picking tool 110 to the other picking tool 110′. In the shown embodiment, picking tool 110 is a vacuum suction tool lifting the released electronic component 100 by a vacuum force in between. Subsequently, the electronic component 100 is placed by the further picking tool 110′ with said one side on the carrier 108. In the shown embodiment, the other picking tool 110′ is a further vacuum suction tool holding the electronic component 100 by a vacuum force in between.

The embodiment of FIG. 9 has the advantages of a small number of process stages, a fast release from the temporary carrier 112, significantly less issues compared to the usage of needles, a low impact due to release by laser (so that thinner silicon chips are possible), no die knocking occurs, carrier recycling is easy (in particular without etching or thinning), and a long lifetime of the temporary carrier 112 can be achieved. Furthermore, a particularly gentle way of doing die picking for thin and fragile dies may be provided. A low manufacturing effort may be obtained with respect to reduced edge issues. In particular, laser-assisted die release has turned out as highly advantageous.

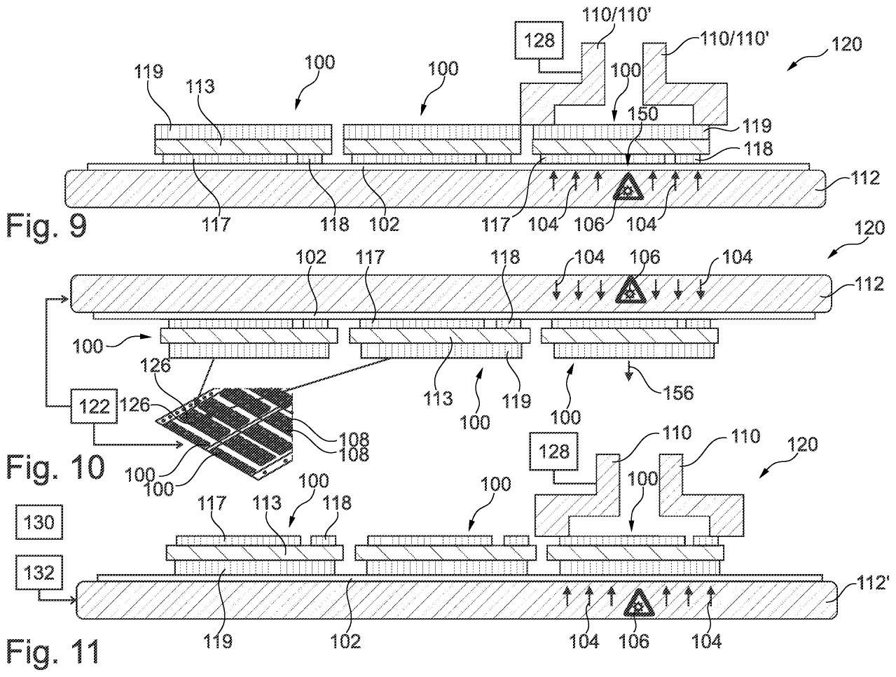

FIG. 10 illustrates an equipment 120 according to another exemplary embodiment. In this embodiment, electronic components 100 are mounted on an adhesive base structure 102 applied on a bottom side of an optically transparent temporary carrier 112. Thereafter, a part of the base structure 102 relating to a specific electronic component 100 is dissolved by irradiating said part of the base structure 102 with electromagnetic radiation 104 emitted by an electromagnetic radiation source 106 to thereby release the electronic component 100. As a result, the released electronic component 100 drops downwardly by the force of gravity, see reference sign 156, on a permanent carrier 108 (not shown in FIG. 10). This process can be executed for example as described above referring to FIG. 1, FIG. 3 or FIG. 6.

To put it shortly, the embodiment of FIG. 10 executes a direct transfer of an electronic component 100 by a laser-assisted release. This may lead to an automatic drop of the released electronic component 100 to a leadframe-type carrier 108.

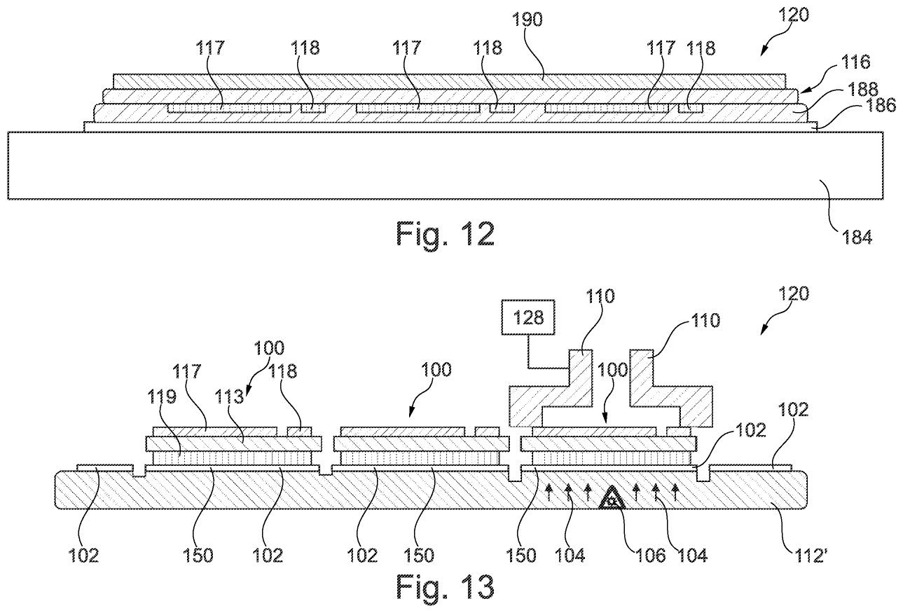

FIG. 11 illustrates an equipment 120 according to still another exemplary embodiment. The embodiment of FIG. 11 involves mounting and re-mounting of electronic components 100 on two temporary carriers 112, 112′ (only one of which being shown in FIG. 11). A simple pick and place tool and laser-assisted chip release may be implemented as well.

The embodiment of FIG. 11 may be based on a structure as shown in FIG. 9, but without the two-part picking tool 110/110′ illustrated there. Starting from such a structure, the upper main surface of the electronic components 100 according to FIG. 9 may be attached to a further temporary carrier 112′, such as a tape or hard carrier. More specifically, the pads 119 of the electronic components 100 may be connected to an adhesive base structure 102 on the further temporary carrier 112′. Thereafter, the initial temporary carrier 112 may be detached, for instance by irradiation with electromagnetic radiation or by supplying heat. The obtained structure may be turned upside down, which may lead to the structure shown in FIG. 11 (without picking tool 110). As shown in FIG. 11, a portion of the adhesive base structure 102 on the further temporary carrier 112′ may then be selectively irradiated with electromagnetic radiation 104 emitted by electromagnetic radiation source 106 for releasing it from the further temporary carrier 112′. After that, the released electronic component 110 may be picked by picking tool 110 of a pick and place assembly 128 at the exposed main surface having pads 117, 118 and may be placed with the exposed pad 119 on a target surface (for instance a permanent carrier 108).

Hence, already before the picking, the electronic components 100 are placed at the side with its pads 119 on temporary carrier 112′. After the picking, the picked electronic component 100 is placed with the side with pad 119 on the carrier 108. After having mounted the electronic components 100 on the adhesive base structure 102 on the optically transparent further temporary carrier 112′, at least part of the base structure 102 is irradiated with electromagnetic radiation 104 through the optically transparent further temporary carrier 112′ for dissolving the base structure 102 to thereby release the assigned electronic component 100.

In order to execute the described method, equipment 120 shown in FIG. 11 may be used. Said equipment 120 comprises an attaching unit 130 (shown schematically in FIG. 11) which is configured for attaching a preform of the electronic component 100 at one side to a temporary carrier 112 during manufacture of the electronic component 100, see FIG. 9 (without picking tool 110/110′). A further attaching unit 132 (shown schematically in FIG. 11) is configured for attaching the electronic component 100 at an opposing other side to the further temporary carrier 112′. The electromagnetic radiation source 106 also forms part of equipment 120 and is configured for irradiating a portion of the adhesive base structure 102, arranged between the further temporary carrier 112′ and the electronic components 100, to thereby release the electronic component 100 from the adhesive base structure 102. The pick and place unit 128 of equipment 120 is configured for, after the releasing, picking the electronic component 100 at said one side by picking tool 110, and for subsequently placing the electronic component 100 on a carrier 108.

Thus, the embodiment of FIG. 11 implements only a single picking tool 110 and uses two temporary carriers 112, 112′. Due to the re-mounting (for example re-lamination) of the electronic components 100 from temporary carrier 112 to further temporary carrier 112′, the back side of the electronic components 100 (to be attached to carrier 108 according to a certain application) is already on the right side, so that a single picking tool 110 is sufficient.

As an alternative to FIG. 11, is also possible that the illustrated adhesive base structure 102 is patterned so as to have gaps between adjacent electronic components 100.

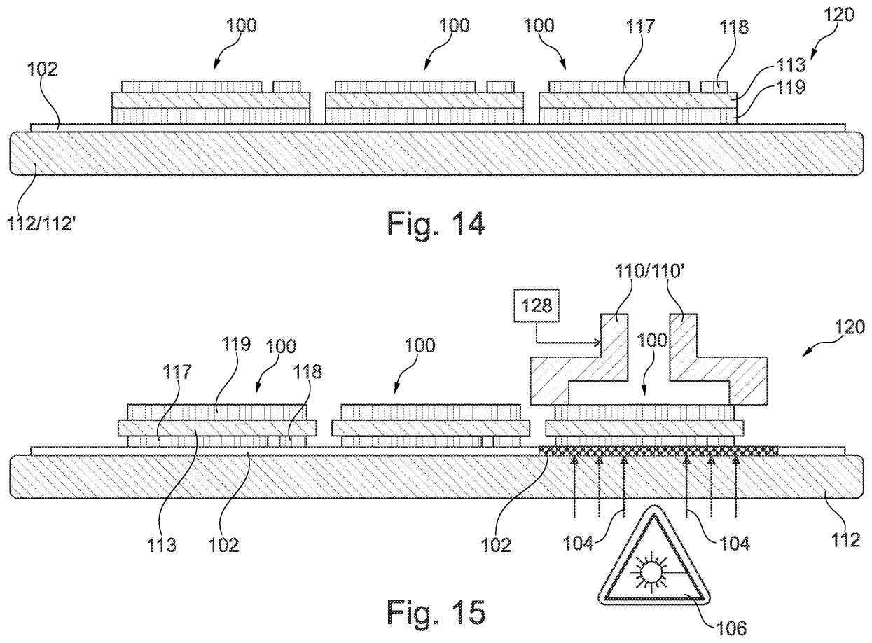

FIG. 12 and FIG. 13 show different views of structures obtained during carrying out a method according to an exemplary embodiment. In particular, it may be possible to use a UV sensitive adhesive for all processes (in particular singulation and die attach).

Referring to FIG. 12, soft glue 188 may be applied to a grinding carrier 184 (for instance made of glass) with a laser ashing layer 186 in between. A wafer 116 with pads 117, 118 on a front side thereof may be assembled on the soft glue 188. A back side metallization layer 190 may be formed on top of wafer 116.

Referring to FIG. 13, a plurality of electronic components 100 with pads 117, 118 on the front side and pad 119 on the back side are mounted on an adhesive base structure 102 which is already patterned to form individual mounting portions 150, one for each electronic component 100.

Advantageously, re-mounting of the electronic components 100 on UV sensitive adhesive on temporary carrier 112′ may be executed. Singulation may be accomplished by laser treatment and/or mechanical treatment. A thickness of the UV adhesive may be in a range from 0.5 μm to 15 μm, which is possible in all embodiments. A pick and place process may be executed with a picking tool 110. Laser-assisted release of the electronic components 100 may be executed.

In case of an unpatterned back side metal, a UV sensitive material can be spinned on the wafer back side before remounting on a tape.

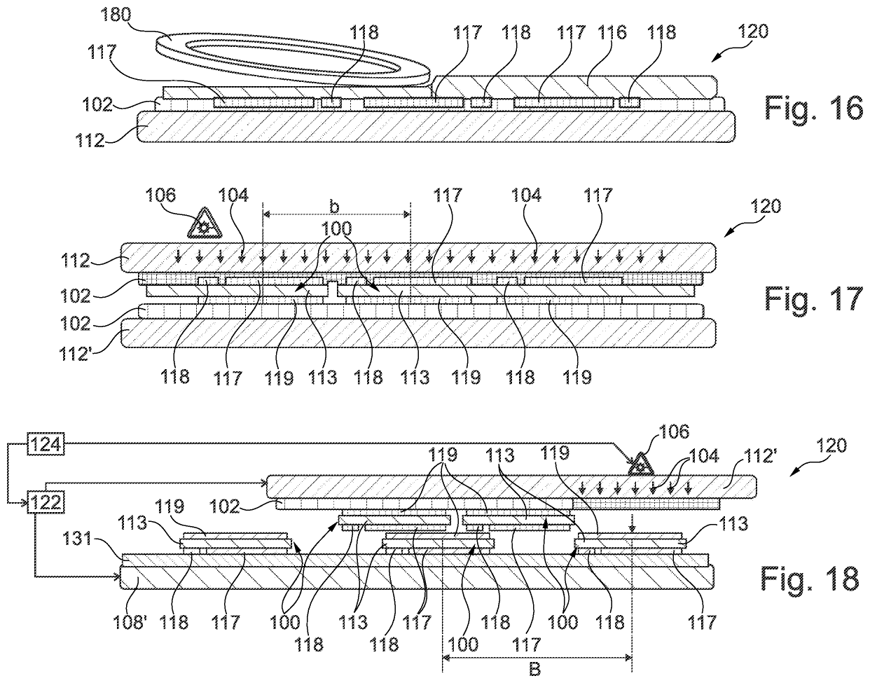

FIG. 14 and FIG. 15 show different views of structures obtained during carrying out a method according to an exemplary embodiment.

Referring to FIG. 14, it may be possible to use UV sensitive adhesive for die attach only. Re-mounting to tape may occur with UV sensitive adhesive.

Referring to FIG. 15, a dicing tape may be used as temporary carrier 112. A pick and place process may be executed by flip tools with laser release. A direct transfer of an electronic component 100 may be accomplished with laser release.

In case of an unpatterned back side metal, a UV sensitive material can be spinned on the wafer back side before remounting on a tape.

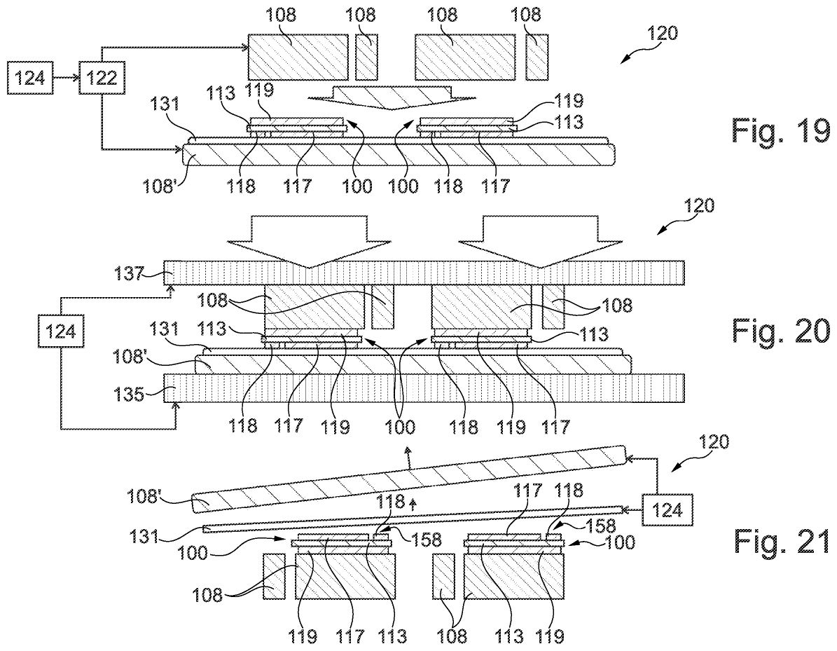

FIG. 16 to FIG. 21 show different views of structures obtained during carrying out a method according to an exemplary embodiment.

In particular, this embodiment relates to a batch die transfer process. Such a process may be in particular advantageous for thin dies, for instance for electronic components having a thickness below 200 μm, in particular below 100 μm. The described embodiment implements laser release in combination with pitch adaption.

Generally, ultra-thin dies need to be transferred from a wafer to a substrate by low impact and low effort process procedures, since their small thickness renders them prone to damage. Diffusion soldering may be superior with respect to Rth and Ron properties of the obtained packages. Besides, it may prevent die tilt and may be compatible with many chip technologies and packaging technologies (for example leadframe, embedding in PCB, embedding of leadframe, embedded die in mold). Especially for ultra-thin dies, diffusion soldering can provide reduced solder thickness and can avoid solder creepage at a die edge. However, conventional dicing foil adhesion strength and variation of this parameter does not fit properly to the fragility of the thin dies during pick-up. Diffusion soldering may be slow and costly when done with a heated substrate (for instance at a temperature of 360° C.) and for each die individually in a serial process. During processing, dies may be grinded and backside sputtered on a glass carrier. Following this, they may be transferred to a dicing tape and may be separated. In a backend, they may be sequentially picked and placed on leadframes. However, the pick and place process may be slow. Additionally, the process may come to an end with decreasing chip thickness and increasing brittleness, for instance for electronic components based on silicon carbide (SiC) technology. The poor control of dicing foil adhesion may lead to picking problems. This issue may increase with even thinner chips.

In order to overcome at least part of the aforementioned and/or other shortcomings, the embodiment of FIG. 16 to FIG. 21 transfers singulated dies via laser transfer to another carrier with the following properties: Pitches (for instance in one or two perpendicular directions in the horizontal plane) on wafer and on carrier level may be different. Pitches (for instance in one or two perpendicular directions in the horizontal plane) on the carrier may be identical with pitches on for example a permanent carrier (such as a leadframe, DCB, etc.) in both directions in the horizontal plane. Intermediate carrier material may be implemented which is stable for temperatures for batch diffusion soldering (for example stable at least up to 220° C., or even up to 250° C. or more). Said intermediate carrier material may be sticky to keep chips in place during transport and during positioning on a leadframe or the like. The carrier and sticky material may be removable without residues after batch soldering.

An embodiment of the mentioned process will be described in the following in further detail:

Starting point may be the structure shown in FIG. 16, which corresponds to the structure shown in FIG. 4, so that reference is made to the description of FIG. 4 and FIG. 5 for the sake of conciseness. A glass carrier 112 used for grinding and singulation has a base structure 102 thereon which may be made of a photopolymer as adhesion agent. Grinding, backside preparation and singulation on the glass carrier 112 may be executed as described above. The sticky medium of the base structure 102 may be glue with light to heat conversion (LTHC) release coating. The transparent carrier 112 may be a glass carrier.

Referring to FIG. 17, the base structure 102 is irradiated with electromagnetic radiation 104 emitted by an electromagnetic radiation source 106 (such as a laser source) for releasing the electronic components 100 from temporary carrier 112 by at least partially dissipating base structure 102 or by converting base structure 102 into a non-adhesive state. A further temporary carrier 112′ is arranged beneath the released electronic components 100 so that the released electronic components 100 are attached to a further base structure 102 on the further temporary carrier 112′. Hence, a remounting of the electronic components 100 on transparent carrier 112′ with photopolymer-interface structure 102 is accomplished. This may bring the pads 117 to 119 of the electronic components 100 into a desired orientation. If this is not required or desired, the process of FIG. 17 can be omitted.

FIG. 17 also illustrates a pitch, b, i.e. a characteristic center-to-center distance between adjacent electronic components 100 or functional portions thereof corresponding to wafer level. As shown in FIG. 17, different electronic components 100 may have different sizes and/or different numbers of pads 117 to 119.

Referring to FIG. 18, the bottom portion of the structure shown in FIG. 17 (with identical electronic components 100 being shown in FIG. 18) is turned upside down so that a further temporary carrier 108′ is arranged below the attached electronic components 100. The further temporary carrier 108′ may be made of a highly temperature resistant material, for instance may be a metal plate. Under control of a control unit 124, an alignment unit 122 may mutually move temporary carriers 112′, 108′ relative to each other for alignment purposes, or more specifically for pitch adaptation.

More specifically, a high temperature resistant soft and sticky layer 131 made of a material being removable without residues may be arranged on the further temporary carrier 108′ facing the electronic components 100 attached on base structure 102 of temporary carrier 112′.

In the shown and described arrangement, it may be possible to dissolve at least part of the base structure 102 by irradiating it with electromagnetic radiation 104 of an electromagnetic radiation source 106. This may be accomplished to release the electronic components 100 from temporary carrier 112′ to transfer the plurality of electronic components 100 to the further temporary carrier 108′. For instance, the electronic components 100 may fall downwardly under the force of gravity onto the soft and sticky layer 131 on further temporary carrier 108′. Advantageously, this transfer of the electronic components 100 from temporary carrier 112′ to temporary carrier 108′ may be executed with increased pitch B>b of the electronic components 100 on temporary carrier 108′ compared with previous pitch b of the electronic components 100 on temporary carrier 112′. To put it shortly, said pitch adaptation may adjust the component-to-component distances of the electronic components 100 to comply with a pitch B of permanent carriers 108, as shown in FIG. 19.

Thus, a high speed laser assisted transfer of dies to the intermediate carrier 108′ with sticky medium may be accomplished with pitch adaption on the fly. Hence, a remounting of the electronic components 100 on the heat resistant carrier-foil arrangement 108′, 131 with changed pitch B may be carried out. The changed pitch B corresponds to a leadframe pitch (see FIG. 19).

Referring to FIG. 19, permanent carriers 108, which are here embodied as leadframes structures, are arranged on top of the structure shown on the bottom of FIG. 18. The permanent carriers 108 are aligned with the electronic components 100 on carrier 108′ in accordance which the changed pitch B. In other words, pitch B of the electronic components 100 on the temporary carrier 108′ may be identical to the pitch B of the permanent carriers 108. The leadframe structures shown as permanent carriers 108 in FIG. 19 may be substituted by other permanent carriers 108, for example DBC, AMB, IMS, PCB, a laminate, in other embodiments.

Although not shown, a solder layer may be formed on a surface of the permanent carriers 108 facing the electronic components 100 and/or on a surface of the electronic components 100 facing the permanent carriers 108. Such a solder layer may be configured for diffusion soldering and may be made for example of NiSn.

Although not shown in FIG. 19, it may be alternatively also possible to turn the temporary carrier 108′ with the attached electronic components 100 upside down and arrange the permanent carriers 108 beneath the electronic components 100 on the temporary carrier 108′. Thus, in an alternative embodiment, an optional remounting for upside-up arrangement may be carried out. Batch diffusion soldering may then be executed with the intermediate carrier 108′ on top.

Referring to FIG. 20, hot plates 135, 137 may be arranged above and below the structure of FIG. 19 for applying mechanical pressure and for providing heat. Consequently, all electronic components 100 are connected to an assigned permanent carrier 108 by diffusion soldering. This transfers the plurality of electronic components 100 from the further carrier 108′ to the permanent carriers 108. This is accomplished by simultaneous or batch diffusion soldering under application of pressure and heat provided by the hot plates 135, 137. Advantageously, this leads to batch diffusion soldering.

Referring to FIG. 21, temporary carrier 108′ and soft and sticky layer 131 may be removed without residues from the obtained packages 158.

In an abstract formulation, the embodiment of FIG. 16 to FIG. 21 discloses a method which comprises irradiating at least part of an adhesive base structure 102 on a temporary carrier 112, 112′ with electromagnetic radiation 104 to thereby release a plurality of electronic components 100 from the base structure 102 to transfer the electronic components 100 to a further carrier 108′ with changed pitch b->B. The method further comprises subsequently transferring the electronic components 100 to one or more permanent carriers 108 in accordance with the changed pitch B, and batch soldering the electronic components 100 on the one or more permanent carriers 108.

In an abstract formulation, the embodiment of FIG. 16 to FIG. 21 discloses an equipment 120 comprising an electromagnetic radiation source 106 configured for irradiating an adhesive base structure 102 on a temporary carrier 112, 112′ on which a plurality of electronic components 100 is mounted to thereby release the electronic components 100 from the base structure 102. The equipment 120 further comprises an alignment unit 122 configured for aligning a mutual position between, on the one hand, a further carrier 108′ for carrying the electronic components 100 and, on the other hand, the released electronic components 100 to transfer the electronic components 100 to the further carrier 108′ with changed pitch B. The alignment unit 122 may be further configured for aligning the further carrier 108′ with one or more permanent carriers 108 for subsequently transferring the electronic components 100 to and connecting the electronic components 100 with the one or more permanent carriers 108 in accordance with the changed pitch B.

The soft and sticky layer 131 may be embodied as tacking film for supporting the batch diffusion soldering process. Thus, the soft and sticky layer 131 may be a film with tacking surface. Corresponding adhesion forces may be for example van der Waals forces. The soft and sticky layer 131 may be for example silicone based, may comprise cellophane, etc. The soft and sticky layer 131 may be a film applied on hard carrier 108′ (which may be flat or a roller) or in a frame.

Various alternatives to the embodiment of FIG. 16 to FIG. 21 may be implemented. For instance, the electronic components 100 may be assembled on the permanent carrier(s) 108 in a source down configuration. A relamination stage may be dispensable in such an embodiment, and a photopolymer may be formed on the grinding carrier. In an embodiment, two times relamination may be carried out.

In yet another embodiment, a pitch change may occur during the first remounting from the glass carrier (for example so that the processing according to FIG. 17 can be omitted, and the process may continue with FIG. 18). For example, this may be accomplished by a photopolymer on the first carrier.

Furthermore, alternative interconnects between electronic components 100 and permanent carriers 108 are possible, for example a glue interconnect (for example chips with glue depot), a soft solder (for example using tin, silver, lead), a sinter material (for example using silver and/or copper), a copper-copper connection (for example formed by hybrid bonding or by ultrasonic welding), etc.

Still referring to the embodiment of FIG. 16 to FIG. 21, a process is disclosed which includes:
Thinning a wafer on a first carrier (see FIG. 16)
Separating dies from the wafer (this can be done at several stages, see for instance FIG. 16)
Transferring the dies to a second, transparent carrier with a layer which can be photo-activated (see FIG. 17)
Transferring the dies to a third carrier, which is capable to withstand process temperatures of a backend process by evaporating the photo-component of the layer by a laser and changing the pitch to the backend requirements (see FIG. 18)
Aligning permanent carriers (such as substrates) to the dies on the third carrier (see FIG. 19)
Connecting the dies and the permanent carriers by a hot process (see FIG. 20)
Removing the third carrier (see FIG. 21).

Optionally, it may be possible to transfer different chip types to the third carrier for multi-chip products. For example, it may be possible to transfer chips to carriers for direct encapsulation.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A method, comprising:
mounting a plurality of electronic components on assigned parts of an adhesive base structure on a temporary carrier;
dissolving said parts of the base structure by irradiating said parts of the base structure with electromagnetic radiation to thereby release the electronic components; and
transferring the electronic components to and batch soldering the electronic components on one or more permanent carriers.

2. The method according to claim 1, wherein the electronic components are connected with the at least one permanent carrier by batch diffusion soldering.

3. The method according to claim 1, wherein the electronic components are connected with the at least one permanent carrier by an adhesive medium on a main surface of the at least one carrier, wherein the adhesive medium is at least one of an adhesive solder paste, an adhesive sinter paste, and a glue.

4. The method according to claim 1, wherein the method comprises dissolving said at least part of the base structure so that the base structure is transferred from a component-carrying solid state into a component-releasing dissolved gaseous and/or liquid state.

5. The method according to claim 1, wherein the method comprises irradiating the base structure with an electromagnetic radiation source configured as a laser to thereby release the electronic component.

6. The method according to claim 1 wherein the method comprises aligning a mutual position between, on the one hand, a carrier for carrying the electronic component and, on the other hand, the released electronic component so that the electronic component is transferred and lands on the carrier.

7. The method according to claim 1, wherein the method comprises dissolving the at least part of the base structure while the electronic component is located at a bottom side of the adhesive base structure.

8. The method according to claim 1, wherein the method comprises dissolving the at least part of the base structure while the electronic component is located at a top side of the adhesive base structure.

9. The method according to claim 8, wherein the method comprises, after the dissolving, picking the electronic component at one side thereof by a picking tool, in particular a suction-type picking tool, and subsequently placing the picked electronic component on a carrier.

10. The method according to claim 9, wherein the method comprises, after the picking, further picking the electronic component at an opposing other side thereof by another picking tool, in particular another suction-type picking tool, and subsequently placing the electronic component with said one side on the carrier, wherein in particular the method comprises, before the picking, attaching the electronic component at an opposing other side to a temporary carrier, and, after the picking, placing the picked electronic component with said other side on the carrier.

11. The method according to claim 1, wherein the method comprises dissolving the at least part of the base structure by irradiating with electromagnetic radiation to thereby release a plurality of electronic components to transfer the plurality of electronic components to a further carrier with changed, in particular increased, pitch compared with another pitch of the plurality of electronic components on the temporary carrier.

12. The method according to claim 11, comprising at least one of the following features:
wherein the further carrier is a further temporary carrier;
wherein the further carrier is a high temperature resistant carrier, in particular is temperature resistant at least up to 220° C. and/or is a metal carrier;
wherein the method comprises arranging a soft and sticky layer, in particular a high temperature resistant layer, more particularly temperature resistant at least up to 220° C., between the plurality of electronic components and the further carrier;
wherein the method comprises transferring the plurality of electronic components from the further carrier to one or more permanent carriers, in particular under application of pressure and heat.

13. The method according to claim 1, comprising at least one of the following features:
wherein the method comprises mounting the electronic component on the adhesive base structure on an optically transparent temporary carrier, and irradiating the base structure with electromagnetic radiation through the optically transparent temporary carrier for dissolving at least part of the base structure;
wherein the method comprises irradiating the base structure by scanning the base structure by an electromagnetic radiation source by moving, on the one hand, the electromagnetic radiation source and/or an electromagnetic radiation beam thereof and, on the other hand, the base structure relative to each other;
wherein the method comprises irradiating the base structure through a partially optically transparent and partially opaque mask arranged between the base structure and the electromagnetic radiation source, in particular a greyscale mask configured for irradiating a portion of the base structure corresponding to an edge of the electronic component with higher intensity than another portion of the base structure corresponding to a center of the electronic component.

14. The method according to claim 1, wherein the method comprises thinning and thereafter separating a wafer into a plurality of electronic components while the wafer is arranged on the adhesive base structure.

15. The method according to claim 14, wherein the method comprises, after the thinning and before the separating, forming pads on a thinned surface of the wafer.

16. An equipment, comprising:
an electromagnetic radiation source configured for irradiating at least a mounting portion of an adhesive base structure on a temporary carrier, on which mounting portion an electronic component is mounted, to thereby release the electronic component from the mounting portion; and
an alignment unit for aligning a mutual position between a carrier for carrying the electronic component and the released electronic component so that the electronic component is transferred and lands on the carrier;
wherein the equipment is configured for batch soldering a plurality of the electronic components on one or more permanent carriers.

17. The equipment according to claim 16, comprising one of the following features:
wherein the equipment is configured so that the released electronic component is falling downwardly by gravity so that the downwardly falling electronic component lands on the carrier;
wherein the equipment is configured so that the released electronic component is transferred to land on the carrier by gas pressure, or by gravity or expansion of the base structure or of an intermediate layer;
wherein said equipment comprises the adhesive base structure which is configured for dissolving when being irradiated with electromagnetic radiation;
wherein said equipment comprises the adhesive base structure which is configured for being converted from an adhesive state into a non-adhesive or less adhesive state when being irradiated with electromagnetic radiation;
wherein the electromagnetic radiation source comprises a laser.

18. The equipment according to claim 15, comprising one of the following features:
wherein the alignment unit is configured for statically placing a vertically downwardly falling electronic component in lateral alignment with the statically placed carrier so that the vertically downwardly falling electronic component lands on the carrier;
wherein the alignment unit is configured for dynamically moving the electronic component and the carrier relatively to each other along a lateral direction transverse to gravity so that a downwardly falling electronic component lands on the carrier under consideration of said lateral motion.

19. The equipment according to claim 15, comprising a control unit configured for controlling the electromagnetic radiation source for executing said irradiating and the alignment unit for executing said aligning.

20. The equipment according to claim 15, comprising at least one of the following features:
comprising the carrier which comprises an adhesive medium on a main surface at which the landing electronic component will be stopped, wherein in particular the adhesive medium comprises at least one of adhesive solder paste, adhesive sinter paste, and glue;
comprising the carrier being a high temperature resistant carrier covered by a high temperature resistant soft and sticky layer;
comprising the electronic component having pads on both opposing main surfaces and/or experiencing vertical current flow during operation;
wherein the equipment is configured for controlling irradiation of at least the mounting portion of the adhesive base structure with electromagnetic radiation to thereby release a plurality of electronic components from the mounting portion to transfer the plurality of electronic components to the carrier with changed, in particular increased, pitch compared with another pitch of the plurality of electronic components on the temporary carrier.
